(19) United States
(12) Patent Application Publication
(10) Pub. No.: US 2007/0261951 A1
(43) Pub. Date: Nov. 15, 2007

(54) REACTIVE SPUTTERING ZINC OXIDE TRANSPARENT CONDUCTIVE OXIDES ONTO LARGE AREA SUBSTRATES

(76) Inventors: Yan Ye, Saratoga, CA (US); Ankur Kadam, Santa Clara, CA (US); Yanping Li, Albany, CA (US); Allen Ka-Ling Lau, Cupertino, CA (US); Makoto Inagawa, Palo Alto, CA (US); Bradley O. Stimson, Monte Sereno, CA (US); Akihiro Hosokawa, Cupertino, CA (US)

Correspondence Address: PATTERSON & SHERIDAN, LLP, 3040 POST OAK BOULEVARD, SUITE 1500, HOUSTON, TX, 77056, US

(21) Appl. No.: 11/697,476

(22) Filed: Apr. 6, 2007

Related U.S. Application Data
(63) Continuation-in-part of application No. 11/399,233, filed on Apr. 6, 2006.
(60) Provisional application No. 60/807,391, filed on Jul. 14, 2006.

(51) Int. Cl. C23C 14/00

(52) U.S. Cl. 204/192.1; 204/298.02

(57) ABSTRACT

The present invention generally comprises one or more cooled anodes shadowing one or more gas introduction tubes where both the cooled anodes and the gas introduction tubes span a processing space defined between one or more sputtering targets and one or more substrates within a sputtering chamber. The gas introduction tubes may have gas outlets that direct the gas introduced away from the one or more substrates. The gas introduction tubes may introduce reactive gas, such as oxygen, into the sputtering chamber for depositing TCO films by reactive sputtering. During a multiple step sputtering process, the gas flows (i.e., the amount of gas and the type of gas), the spacing between the target and the substrate, and the DC power may be changed to achieve a desired result.

### CROSS-REFERENCE TO RELATED APPLICATIONS

This application is a continuation-in-part of co-pending U.S. patent application Ser. No. 11/399,233 (APPM/10586), filed Apr. 6, 2006. This application also claims the benefit of U.S. Provisional Patent Application Serial No. 60/807,391 (APPM/11277L), filed Jul. 14, 2006. Each of the aforementioned related patent applications is herein incorporated by reference.

### BACKGROUND OF THE INVENTION

1. Field of the Invention

Embodiments of the present invention generally relate to a physical vapor deposition (PVD) system and methods for depositing transparent conductive oxides (TCO) onto large area substrates by reactive sputtering.

2. Description of the Related Art

PVD using a magnetron is one method of depositing material onto a substrate. During a PVD process a target may be electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, oxygen or nitrogen, to reactively deposit a compound on the substrate.

Direct current (DC) sputtering and alternating current (AC) sputtering are forms of sputtering in which the target is biased to attract ions towards the target. The target may be biased to a negative bias in the range of about −100 to −600 V to attract positive ions of the working gas (e.g., argon) toward the target to sputter the atoms. The sides of the sputter chamber may be covered with a shield to protect the chamber walls from sputter deposition. The shield may be electrically grounded and thus provide an anode in opposition to the target cathode to capacitively couple the target power to the plasma generated in the sputter chamber.

During sputtering, material may sputter and deposit on the exposed surfaces within the chamber. When the temperature fluxuates from a processing temperature to a lower, non-processing temperature, material that has deposited on the exposed surfaces of the chamber may flake off and contaminate the substrate.

When depositing thin films over large area substrates such as glass substrates, flat panel display substrates, solar cell panel substrates, and other suitable substrates, uniform deposition on the substrate may be difficult. Therefore, there is a need in the art to reduce flaking in PVD chambers, while also uniformly depositing onto a substrate.

### SUMMARY OF THE INVENTION

The present invention generally comprises one or more cooled anodes shadowing one or more gas introduction tubes where both the cooled anodes and the gas introduction tubes span a processing space defined between one or more sputtering targets and one or more substrates within a sputtering chamber. The gas introduction tubes may have gas outlets that direct the gas introduced away from the one or more substrates. The gas introduction tubes may introduce reactive gas, such as oxygen, into the sputtering chamber for depositing TCO films by reactive sputtering. During a multiple step sputtering process, the gas flows (i.e., the amount of gas and the type of gas), the spacing between the target and the substrate, and the DC power may be changed to achieve a desired result.

In one embodiment, a physical vapor deposition apparatus is disclosed. The apparatus comprises one or more sputtering targets, a substrate support, one or more anodes disposed between the one or more sputtering targets and the substrate support, and one or more gas distribution tubes coupled with the one or more anodes and one or more gas sources.

In another embodiment, a physical vapor deposition apparatus is disclosed. The apparatus comprises a chamber body, one or more sputtering targets disposed within the chamber body, a substrate support disposed within the chamber body, and one or more tubes disposed within the chamber body between the one or more sputtering targets and the substrate support, the one or more tubes comprising an anode and one or more gas outlets.

In yet another embodiment, a physical vapor deposition method is disclosed. The method comprises positioning at least one tube assembly in a processing space between one or more sputtering targets and a susceptor, the tube assembly comprising an anode with a cooling channel therein and a gas distribution tube, cooling the at least one tube assembly with a cooling fluid flowing within the anode, flowing processing gas through the gas distribution tube, and sputtering material from the one or more sputtering targets onto a substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a cross-sectional schematic view of a PVD chamber according to one embodiment of the invention.

FIG. 1B is a close up view of FIG. 1A.

FIG. 2A is a schematic perspective view of gas introduction tubes coupled to cooled anodes according to one embodiment of the invention.

FIG. 2B is a schematic perspective view of the cooled anodes and gas introduction tubes of FIG. 2A passing through the chamber walls.

FIG. 3 is a cross sectional view of a coupling through the wall of a cooled anode and a gas introduction tube according to one embodiment of the invention.

FIG. 4A is a perspective view of a cooled anode coupled to a gas introduction tube according to one embodiment of the invention.

FIG. 4B is a cross sectional view of the cooled anode coupled to the gas introduction tube of FIG. 4A.

FIG. 5A is a perspective view of a cooled anode coupled to a gas introduction tube according to one embodiment of the invention.

FIG. 5B is a cross sectional view of the cooled anode coupled to the gas introduction tube of FIG. 5A.

FIG. 6A is a perspective view of a cooled anode coupled to a gas introduction tube according to one embodiment of the invention.

FIG. 6B is a cross sectional view of the cooled anode coupled to the gas introduction tube of FIG. 6A.

FIG. 7A is a perspective view of a cooled anode coupled to a gas introduction tube according to one embodiment of the invention.

FIG. 7B is a cross sectional view of the cooled anode coupled to the gas introduction tube of FIG. 7A.

FIGS. 8A and 8B are schematic representations of single junction and dual/tandem junction film stacks for solar panels according to embodiments of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises one or more cooled anodes shadowing one or more gas introduction tubes where both the cooled anodes and the gas introduction tubes span a processing space defined between one or more sputtering targets and one or more substrates within a sputtering chamber. The gas introduction tubes may have gas outlets that direct the gas introduced away from the one or more substrates. The gas introduction tubes may introduce reactive gas, such as oxygen, into the sputtering chamber for depositing TCO films by reactive sputtering. During a multiple step sputtering process, the gas flows (i.e., the amount of gas and the type of gas), the spacing between the target and the substrate, and the DC power may be changed to achieve a desired result.

The invention is illustratively described and may be used in a PVD chamber for processing large area substrates, such as a 4300 PVD chamber, available from AKT®, a subsidiary of Applied Materials, Inc., Santa Clara, Calif. However, it should be understood that the sputtering target may have utility in other system configurations, including those systems configured to process large area round substrates and those systems produced by other manufacturers.

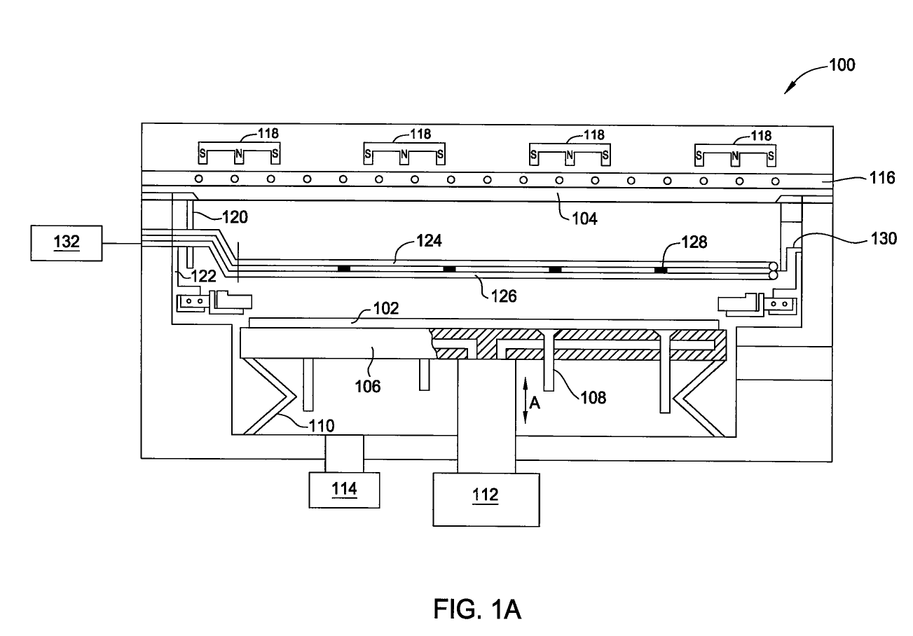

FIG. 1A is a cross-sectional schematic view of a PVD chamber 100 according to one embodiment of the invention. FIG. 1B is a close up view of FIG. 1A. The chamber 100 may be evacuated by a vacuum pump 114. Within the chamber 100, a substrate 102 may be disposed opposite a target 104. The substrate may be disposed on a susceptor 106 within the chamber 100. The susceptor 106 may be elevated and lowered as shown by arrows A by an actuator 112. The susceptor 106 may be elevated to raise the substrate 102 to a processing position and lowered so that the substrate 102 may be removed from the chamber 100. Lift pins 108 elevate the substrate 102 above the susceptor 106 when the susceptor 106 is in the lowered position. Grounding straps 110 may ground the susceptor 106 during processing. The susceptor 106 may be raised during processing to aid in uniform deposition.

The target 104 may comprise one or more targets 104. In one embodiment, the target 104 may comprise a large area sputtering target 104. In another embodiment, the target 104 may comprise a plurality of tiles. In yet another embodiment, the target 104 may comprise a plurality of target strips. In still another embodiment, the target may comprise one or more cylindrical, rotary targets. The target 104 may be bonded to a backing plate 116 by a bonding layer 134. To control the temperature of the target 104, cooling channels 136 may be present in the backing plate 116. One or more magnetrons 118 may be disposed behind the backing plate 116. The magnetrons 118 may scan across the backing plate 116 in a linear movement or in a two dimensional path. The walls of the chamber may be shielded from deposition by a dark space shield 120 and a chamber shield 122.

The grounded chamber walls may function as an anode and attract electrons from the plasma and hence, may tend to create a higher density of plasma near the chamber walls. A higher density of plasma near the chamber walls may increase the deposition on the substrate near the chamber walls and decrease the deposition away from the chamber walls. The grounded susceptor 106, on the other hand, also functions as an anode. For large area substrate deposition, the susceptor 106 may span a significant length of the processing space 158. Thus, the susceptor 106 may provide a path to ground for electrons not only at the edge of the susceptor 106, but also at the middle of the susceptor 106. The path to ground at the middle of the susceptor 106 balances out the path to ground at the edge of the susceptor 106 and the chamber walls because each anode, be it the chamber walls or the susceptor 106, will equally function as an anode and uniformly spread the plasma across the processing space. By uniformly distributing the plasma across the processing space, uniform deposition across the substrate 102 may occur.

When the substrate 102 is an insulating substrate (such as glass or polymer), the substrate 102 is non-conductive and thus electrons may not follow through the substrate 102. As a consequence, when the substrate 102 substantially covers the susceptor 106, the susceptor 106 may not provide sufficient anode surfaces.

For large area substrates 102, such as solar cell panels or substrates 102 for flat panel displays, the size of the substrate 102 blocking the path to ground through the susceptor 106 may be significant. Substrates 102 as large as 1 meter by 1 meter are not uncommon in the flat panel display industry. For a 1 meter by 1 meter substrate 102, a path to ground through the susceptor 106 may be blocked for an area of 1 square meter. Therefore, the chamber walls and the edges of the susceptor 106 that are not covered by the substrate are the only paths to ground for the electrons in the plasma. No path to ground exists near the center of the substrate 102. With a large area substrate 102, a high density plasma may form near the chamber walls and the edge of the susceptor 106 that are not covered by the substrate 102. The high density plasma near the chamber walls and the susceptor 106 edge may thin the plasma near the center of the processing region where no path to ground exists. Without a path to ground near the center of the processing area, the plasma may not be uniform and hence, the deposition on the large area substrate may not be uniform.

To help provide uniform sputtering deposition across a substrate 102, an anode 124 may be placed between the target 104 and the substrate 102. In one embodiment, the anode 124 may be bead blasted stainless steel coated with arc sprayed aluminum. In one embodiment, one end of the anode 124 may be mounted to the chamber wall by a bracket 130. As shown in FIG. 1B, the bracket 130 may be shaped to partially enclose the anode 124 and shield a portion of the anode 124. The bracket 130 bends under the dark space shield 120. As shown in FIG. 1B, a portion of the bracket 130 lies between the dark space shield 120 and the chamber shield 122. The other end of the anode 124 passes through the dark space shield 120 and the chamber wall.

The anode 124 provides a charge in opposition to the target 104 so that charged ions will be attracted thereto rather than to the chamber walls which are typically at ground potential. By providing the anode 124 between the target 104 and the substrate 102, the plasma may be more uniform, which may aid in the deposition.

During processing, the temperatures in the chamber 100 may increase up to about 400 degrees Celsius. Between processing (i.e., when substrates 102 are removed from and inserted into the chamber 100), the temperature of the chamber 100 may be reduced to about room temperature (i.e., about 25 degrees Celsius). The temperature change may cause the anodes 124 to expand and contract. During processing, material from the target 104 may deposit onto the anode 124 because the anode 124 lies between the target 104 and the substrate 102. The material deposited onto the anode 124 may flake off due to expansion and contraction.

Flowing a cooling fluid through the one or more anodes 124 may control the temperature of the anodes 124 and thus reduce any expansion and contraction of the anodes 124. By reducing the amount of expansion and contraction of the anodes 124, flaking of material from the anodes 124 may be reduced.

For reactive sputtering, it may be beneficial to provide a reactive gas into the chamber 100. One or more gas introduction tubes 126 may also span the distance across the chamber 100 between the target 104 and the substrate 102. The gas introduction tubes 126 may introduce sputtering gases such as inert gases including argon as well as reactive gases such as oxygen, nitrogen, etc. The gases may be provided to the gas introduction tubes 126 from a gas panel 132 that may introduce one or more gases such as argon, oxygen, and nitrogen.

The gas introduction tubes 126 may be disposed between the substrate 102 and the target 104 at a location below the one or more anodes 124. The gas outlets 138 on the gas distribution tubes 126 may face away from the substrate 102 to reduce direct exposure of the substrate 102 to processing gas. The gas introduction tubes 126 may have a diameter B about ten times greater than the diameter of the gas outlets 138 so that the flow of gas through each gas outlet 138 may be substantially equal. The anodes 124 may shield the gas introduction tubes 126 from deposition during processing. Shielding the gas introduction tubes 126 with the anodes 124 may reduce the amount of deposition that may cover the gas outlets 138 and clog the gas outlets 138. The anodes 124 may have a larger diameter as shown by arrows B than the diameter of the gas introduction tubes 126 as shown by arrows C. The gas introduction tubes 126 may be coupled with the anodes 124 by one or more couplers 128.

During processing, the gas introduction tubes 126 may be subjected to the same temperature fluxuations as the anodes 124. Therefore, it may be beneficial to cool the gas introduction tubes 126 as well. The coupling 128 may thus be made of thermally conductive material to permit the gas introduction tubes 126 to be conductively cooled. Additionally, the coupling 128 may be electrically conductive as well so that the gas introduction tubes 126 are grounded and function as anodes. In one embodiment, the coupling 128 may comprise metal. In another embodiment, the coupling 128 may comprise stainless steel.

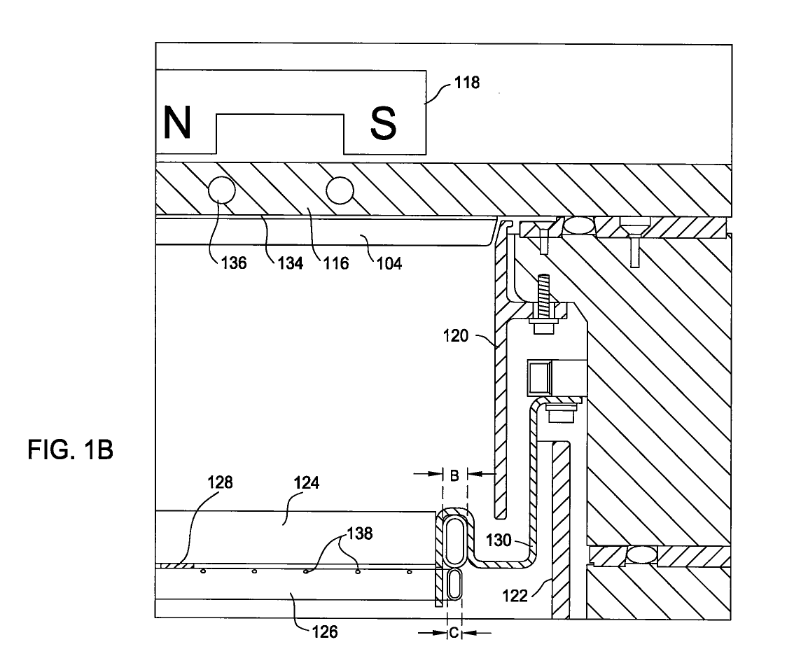

FIG. 2A is a schematic perspective view of gas introduction tubes 204 coupled to cooled anodes 202 according to one embodiment of the invention. FIG. 2A is looking up at the target 214. FIG. 2B is a schematic perspective view of the cooled anodes 204 and gas introduction tubes 202 of FIG. 2A passing through the chamber walls. The anodes 202 may be coupled to the gas introduction tubes 204 by a coupling 206. In one embodiment, six couplings 206 may be spaced across the anodes 204 and gas introduction tubes 204. Both the gas introduction tubes 204 and the cooled anodes 202 may have a substantially U shape whereby the inlet 210 to the anodes 202 and the inlet 208 to the gas introduction tubes 204 and the exit 210 to the anodes 202 and the outlet 208 to the gas introduction tubes 204 may be disposed on the same side of the chamber. The cooling fluid may flow to and from to the chamber through tubes 212.

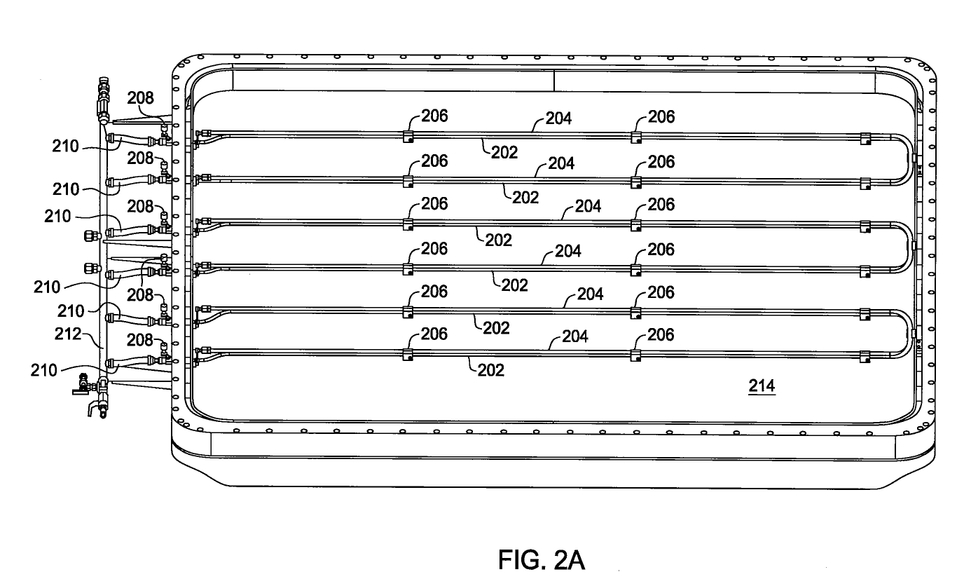

FIG. 3 is a cross sectional view of a coupling 300 through the wall of a cooled anode 302 and a gas introduction tube 304 according to one embodiment of the invention. The coupling 300 may comprise a unitary body 306 through which both the gas introduction tube 304 and the anode 302 may be disposed. The coupling body 306 may comprise an electrically insulating and thermally conductive material.

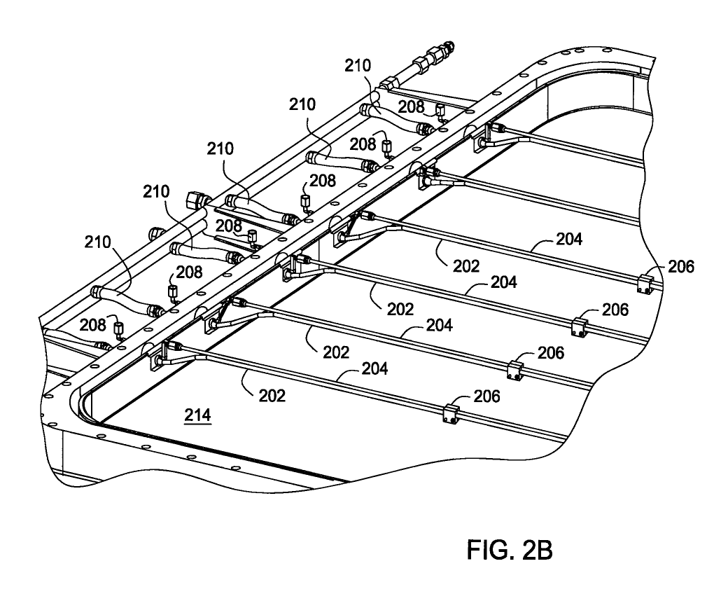

FIGS. 4A-7B disclose various embodiments of cooled anodes coupled to gas introductions tubes. FIG. 4A is a perspective view of the cooled anode 402 coupled to the gas introduction tube 404 according to one embodiment of the invention. FIG. 4B is a cross sectional view of the cooled anode 402 coupled to the gas introduction tube 404 of FIG. 4A. Gas outlets 408 may be disposed facing substantially towards the anode 402. The anode 402 and the gas introduction tubes 404 may be coupled together with a coupling 406. The coupling 406 may comprise a plurality of sections 410a, 410b coupled together by one or more coupling elements 412 at one or more locations along the anode 402 and gas introduction tube 404. As may be seen in FIG. 4B, the diameter of the anode 402 as shown by arrows D may be greater than the diameter of the gas introduction tubes 404 as shown by arrows E.

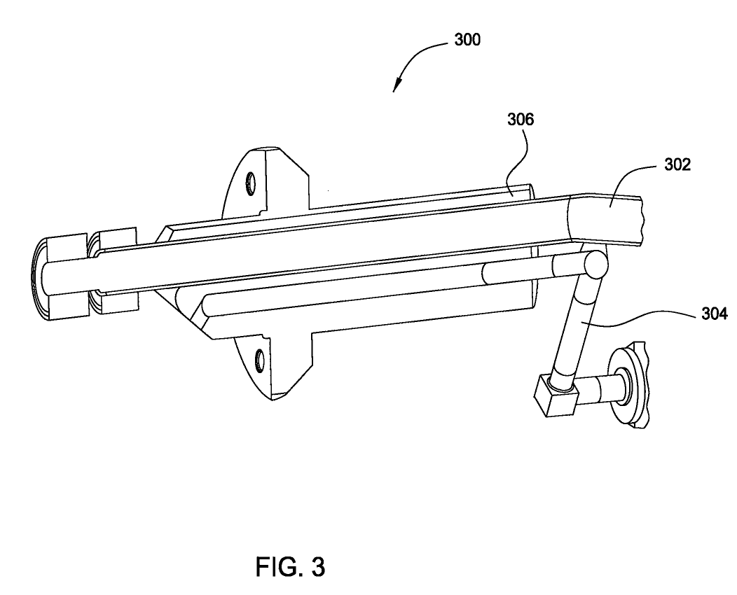

FIG. 5A is a perspective view of a cooled anode 502 coupled to a gas introduction tube 504 according to one embodiment of the invention. FIG. 5B is a cross sectional view of the cooled anode 502 coupled to the gas introduction tube 504 of FIG. 5A. A weld 506 may be used to couple the gas introduction tube 504 to the anode 502 at one or more locations along the gas introduction tube 504 and the anode 502. The diameter of the anode 502 as shown by arrows F may be greater than the diameter of the gas introduction tube 504 as shown by arrows G to shield the gas introduction tube 504 from deposition. One or more gas outlets 508 may be disposed along the gas introduction tube 504. In one embodiment, the gas outlets 508 may be disposed to direct the gas in a direction substantially directly at the anode 502. In another embodiment, the gas outlets 508 may be disposed to direct the gas substantially upward from the substrate, but away from the anode 502.

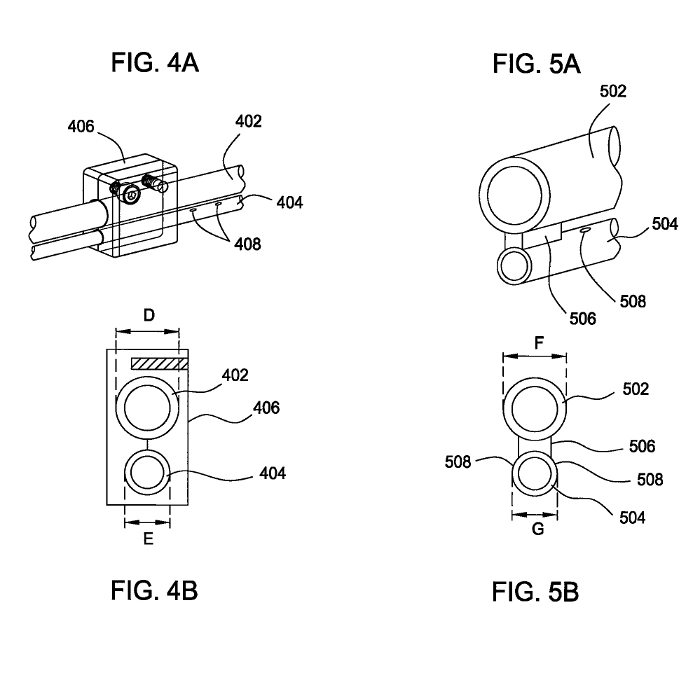

FIG. 6A is a perspective view of a cooled anode 602 coupled to a gas introduction tube 604 according to one embodiment of the invention. FIG. 6B is a cross sectional view of the cooled anode 602 coupled to the gas introduction tube 604 of FIG. 6A. The anode 602 and the gas introduction tube 604 may be coupled together by a weld 606 that runs the length of both the gas introduction tube 604 and the anode 602. Alternatively, the gas introduction tube 604, the weld 606, and the anode 602 may comprise a single unitary piece of material. Gas outlets 608 may be disposed in the gas introduction tube 604 to introduce gas into the processing chamber. The gas outlets 608 may be disposed to direct gas at an angle relative to the anode 602. The diameter of the anode 602 as shown by arrows H may be greater than the diameter of the gas introduction tube 604 as shown by arrows I to shield the gas introduction tube 604 from deposition.

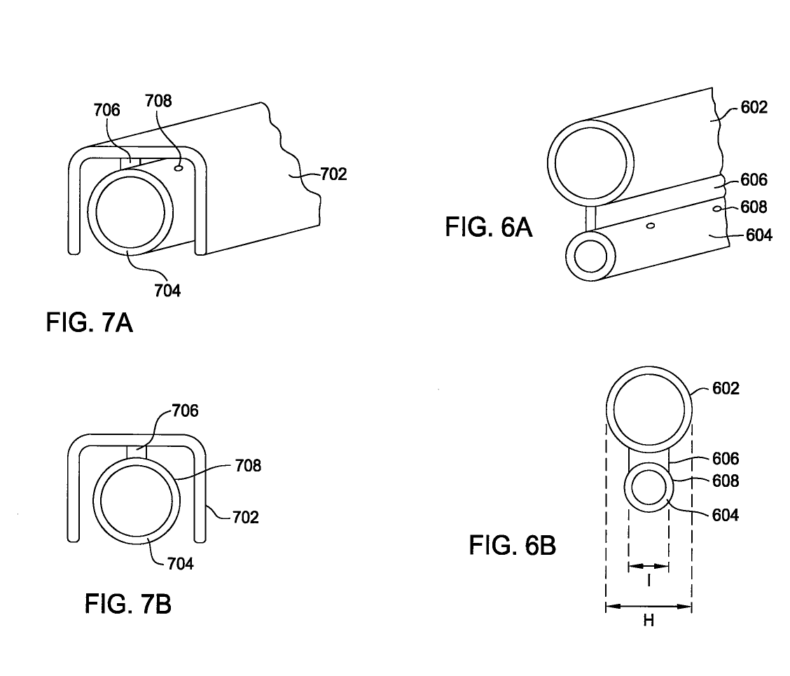

FIG. 7A is a perspective view of a cooled anode 702 coupled to a gas introduction tube 704 according to one embodiment of the invention. FIG. 7B is a cross sectional view of the cooled anode 702 coupled to the gas introduction tube 704 of FIG. 7A. The gas introduction tube 704 may be coupled to the anode 702 by a coupling 706. The anode 706 may substantially enclose the gas introduction tube 704 on three sides. The anode 706 may comprise a substantially inverted U-shaped cross section. The anode 706 may be hollow to permit a cooling fluid to flow therethrough. Gas outlets 708 along the gas introduction tube 704 may permit gas to be emitted from the gas introduction tube 704 and reflected by the anode 702 down towards the processing area.

Reactive Sputtering Process

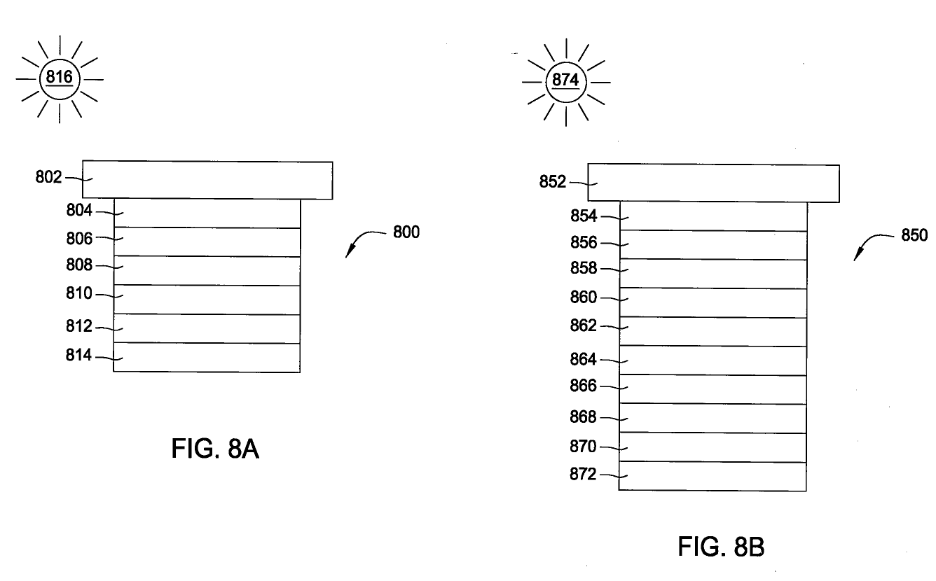

Reactive sputtering may be used to deposit a TCO layer onto a substrate for such applications as solar panels and thin film transistors. TCO layers may be disposed within a solar panel between a reflector layer and a p-i-n structure, between adjacent p-i-n structures, and between glass and a p-i-n structure. FIGS. 8A and 8B are schematic representations of single junction 800 and dual/tandem junction 850 film stacks for solar panels according to embodiments of the invention.

FIG. 8A shows a single junction 800 stack for use in a solar panel according to one embodiment of the invention. The stack comprises, in order relative to the sun 816, a substrate 802, a TCO layer 804, a p-layer 806, an i-layer 808, an n-layer 810, a second TCO layer 812, and a reflector 814. In one embodiment, the substrate 802 may comprise glass and have a surface area of at least about 700 mm×600 mm. The p-layer 806, the i-layer 808, and the n-layer 810 may all comprise silicon. The p-layer 806 may comprise amorphous or microcrystalline silicon doped with well known p-dopants and may be formed to a thickness of about 60 Angstroms to about 400 Angstroms. Similarly, the n-layer 810 may comprise amorphous or microcrystalline silicon doped with well known n-dopants and may be formed to a thickness of about 100 Angstroms to about 500 Angstroms. The i-layer 808 may comprise amorphous or microcrystalline silicon and may be formed to a thickness of about 1,500 Angstroms to about 30,000 Angstroms. The reflector layer 814 may comprise a material selected from the group consisting of Al, Ag, Ti, Cr, Au, Cu, Pt, alloys thereof, or combinations thereof.

FIG. 8B shows a dual/tandem junction 850 stack for use in a solar panel according to one embodiment of the invention. The stack comprises, in order relative to the sun 874, a substrate 852, a TCO layer 854, a p-layer 856, an i-layer 858, an n-layer 860, a second TCO layer 862, a second p-layer 864, a second i-layer 866, a second n-layer 868, a third TCO layer 870, and a reflector 872. The substrate 852, the p-layers 856, 864, the i-layers 858, 866, the n-layers 860, 868, and the reflector 872 may all be as described above with respect to the single junction 800 stack. However, the dual/tandem junction 850 may have different i-layers 858, 866. For example, one i-layer 858, 866 may comprise amorphous silicon while the other comprises microcrystalline silicon so that different portions of the solar spectrum are captured. Alternatively, both i-layers 858, 866 may comprise the same type of silicon (i.e., amorphous or microcrystalline).

The TCO layers 804, 812, 854, 862, 870 may be deposited by reactive sputtering to a thickness of about 250 Angstroms to about 10,000 Angstroms and may comprise one or more elements selected from the group consisting of In, Sn, Zn, Cd, and Ga. One or more dopants may also be present in the TCO. Exemplary dopants include Sn, Ga, Ca, Si, Ti, Cu, Ge, In, Ni, Mn, Cr, V, Mg, SiₓN_{y}, AlₓO_{y}, and SiC. Exemplary compounds that may constitute the TCO layers include binary compounds such as In₂O₃, SnO₂, ZnO, and CdO; ternary compounds such as In₄SnO₁₂, ZnSnO₃, and Zn₂In₂O₅; binary-binary compounds such as ZnO—SnO₂, and ZnO—In₂O₃—SnO₂; and doped compounds such as In₂0₃:Sn (ITO), SnO₂:F, ZnO:In (IZO), ZnO:Ga, ZnO:Al (AZO), ZnO:B, and ZnSnO₃:In.

The TCO layers 804, 812, 854, 862, 870 may be formed by reactive sputtering using a PVD chamber as described above. The sputtering target may comprise the metal of the TCO. Additionally, one or more dopants may be present in the sputtering target. For example, for an AZO TCO layer, the sputtering target may comprise zinc and some aluminum as a dopant. The aluminum dopant in the target may comprise about 2 atomic percent to about 6 atomic percent of the target. By reactively sputtering the TCO, resistivities of less than 5×10⁻⁴ ohm-cm have been achieved. In one embodiment, the resistivity is 3.1×10⁻⁴ ohm-cm. The TCO may have a haze of less than about 1 percent. In one embodiment, the haze may more than 10 percent.

Various sputtering gases may be supplied to the PVD chamber during the sputtering process to reactively sputter the TCO. Sputtering gases that may be supplied include inert gases, oxygen containing gases, non-oxygen containing additives, and combinations thereof. The flow rates for the gases may be proportional to the chamber volume. Exemplary inert gases that may be used include Ar, He, Ne, Xe, and combinations thereof may be provided at a flow rate of about 100 sccm to about 200 sccm. Exemplary oxygen containing gases that may be used include CO, CO₂, NO, N₂O, H₂O, O₂, CₓH_{y}O_{z}, and combinations thereof. The oxygen containing gases may be supplied at a flow rate of about 5 sccm to about 500 sccm. In one embodiment, the oxygen containing gases may be supplied at a flow rate of about 10 sccm to about 30 sccm. Exemplary non-oxygen additive gases that may be used include N₂, H₂, CₓH_{y}, NH₃, NF₃, SiH₄, B₂H₆, PH₃, and combinations thereof. The non-oxygen additive gases may be supplied at a flow rate of about 100 sccm or more. In one embodiment, the non-oxygen additive gases may be supplied at a flow rate of about 200 sccm or more.

To reactively sputter the TCO, DC power may be supplied. In one embodiment, the DC power may be pulsed with a frequency up to about 50 kHz. The duty cycle of the pulsed power may also be adjusted. The temperature of the substrate during sputtering may range from about room temperature to about 450 degrees Celsius. In one embodiment, the substrate temperature may be about 25 degrees Celsius. The spacing between the target and the substrate may be about 17 mm to about 85 mm.

The reactive sputtering of the TCO may occur in multiple steps. By multiple steps it is to be understood to include separate, independent steps as well as a continuous process where one or more deposition parameters change. The power supplied may change during the deposition, the flow rate of the sputtering gases may change during the deposition, the temperature may change during deposition, and the spacing between the target and the substrate may change during the deposition. The changing may occur during a deposition step or between deposition steps. When depositing the TCO, the initial portion of the layer may comprise more metal than oxide because the metal may provide good contact with a layer upon which it is deposited. As the TCO layer gets thicker, more oxygen may be desired in the layer up to the point of complete oxidation. By adjusting the parameters during deposition, the film properties of the TCO, such as a band gap, stress, and refractive index, may be adjusted.

While the foregoing is directed to embodiments of the present invention, other and further embodiments of the invention may be devised without departing from the basic scope thereof, and the scope thereof is determined by the claims that follow.

1. A physical vapor deposition apparatus, comprising:
one or more sputtering targets;
a substrate support;
one or more anodes disposed between the one or more sputtering targets and the substrate support; and
one or more gas distribution tubes coupled with the one or more anodes and one or more gas sources.

2. The apparatus of claim 1, wherein the one or more gas sources comprises an oxygen source.

3. The apparatus of claim 1, wherein the one or more anodes each comprise a body defining a flow path through which a cooling fluid flows.

4. The apparatus of claim 1, wherein the one or more gas distribution tubes are disposed between the one or more anodes and the substrate support.

5. The apparatus of claim 1, wherein the one or more anodes each have a first diameter, and the one or more gas distribution tubes each have a second diameter, wherein the first diameter is greater than the second diameter.

6. The apparatus of claim 1, wherein the one or more gas distribution tubes and the one or more anodes are coupled together with a clamp.

7. The apparatus of claim 6, wherein the clamp comprises a material which is thermally conductive, electrically conductive, or both.

8. The apparatus of claim 1, wherein the one or more gas distribution tubes and the one or more anodes are coupled together by welding.

9. The apparatus of claim 1, wherein the one or more gas distribution tubes comprise one or more openings directed away from the substrate support.

10. The apparatus of claim 9, wherein the one or more gas distribution tubes each have a first diameter and the one or more openings each have a second diameter, and wherein the first diameter is about ten times greater than the second diameter.

11. A physical vapor deposition apparatus, comprising:
a chamber body;
one or more sputtering targets disposed within the chamber body;
a substrate support disposed within the chamber body; and
one or more tubes disposed within the chamber body between the one or more sputtering targets and the substrate support, the one or more tubes comprising an anode and one or more gas outlets.

12. The apparatus of claim 11, wherein the anode comprises a cooling channel.

13. The apparatus of claim 11, wherein the one or more gas outlets are directed away from the substrate support.

14. The apparatus of claim 11, wherein the one or more tubes comprise a hollow anode portion and a gas distribution portion having the one or more gas outlets, and wherein the first hollow anode portion and the first gas distribution portion are a unitary piece of material.

15. The apparatus of claim 14, wherein the first gas distribution portion is disposed between the anode portion and the substrate support.

16. The apparatus of claim 14, wherein the first gas distribution portion is coupled with one or more gas sources.

17. The apparatus of claim 16, wherein the one or more gas sources is an oxygen source.

18. A physical vapor deposition method, comprising:
positioning at least one tube assembly in a processing space between one or more sputtering targets and a susceptor, the tube assembly comprising an anode with a cooling channel therein and a gas distribution tube;
cooling the at least one tube assembly with a cooling fluid flowing within the anode;
flowing processing gas through the gas distribution tube; and
sputtering material from the one or more sputtering targets onto a substrate.

19. The method of claim 18, wherein the one or more sputtering targets comprise zinc.

20. The method of claim 18, wherein the sputtering comprises reactive sputtering.

21. The method of claim 18, wherein the processing gas comprises inert gases, oxygen containing gases, non-oxygen containing additives, and combinations thereof.

22. The method of claim 18, wherein a transparent conductive oxide is sputter deposited onto the substrate.

23. The method of claim 18, further comprising adjusting one or more parameter during sputtering selected from the group consisting of processing gas flow rate, power supplied to the one or more sputtering targets, spacing between the substrate and one or more sputtering targets, and substrate temperature.

24. The method of claim 18, wherein the sputtering occurs at about 25 degrees Celsius.
